(19) United States
(12) Patent Application Publication
(10) Pub. No.: US 2008/0067643 A1
(43) Pub. Date: Mar. 20, 2008

(54) SEMICONDUCTOR DEVICE AND METHOD OF MANUFACTURING THE SAME

(76) Inventors: Shigeki TANAKA, Nanae (JP); Hajime HASEBE, Nanae (JP)

Correspondence Address: MILES & STOCKBRIDGE PC, 1751 PINNACLE DRIVE, SUITE 500, MCLEAN, VA, 22102-3833, US

(21) Appl. No.: 11/851,385

(22) Filed: Sep. 6, 2007

(30) Foreign Application Priority Data
Sep. 14, 2006 (JP) 2006-249138

(51) Int. Cl. H01L 23/495; H01L 21/00

(52) U.S. Cl. 257/666; 257/676; 438/123; 257/E23.031

(57) ABSTRACT

In this invention, it is possible to improve the semiconductor device manufacturing yield. In a leadless package type semiconductor device manufacturing process, there is used a press frame wherein a front end portion each lead is subjected to a coining work. A semiconductor chip-side front end portion of the lead is inclined so as to become lower gradually toward the semiconductor chip. As a result, the amount of depression of the lead front end portion can be made small and hence it is possible to suppress or prevent spring-up of the lead front end portion. Further, the lead front end portion is formed obliquely and the amount of depression thereof is set larger than the thickness of a plating layer formed on the lead front end portion. As a result, when lead frames after formation of the plating layer are conveyed or stored stackedly, it is possible to diminish or prevent the occurrence of an inconvenience such that an overlying lead comes into contact with the plating layer of an underlying lead and causes a frictional scratch to be formed on the plating layer.

### CROSS-REFERENCE TO RELATED APPLICATIONS

The disclosure of Japanese Patent Application No. 2006-249138 filed on Sep. 14, 2006 including the specification, drawings and abstract is incorporated herein by reference in its entirety.

### BACKGROUND OF THE INVENTION

The present invention relates to a semiconductor device manufacturing method and a semiconductor device technique. Particularly, the present invention is concerned with a technique applicable effectively to a method of manufacturing a semiconductor device using a so-called press frame wherein coining is performed for wire-bonded portions of leads and also applicable effectively to the semiconductor device.

In a certain leadless package type semiconductor device typified by QFN (Quad Flat Non leaded package), from the standpoint of ensuring the reliability of bonding between leads and bonding wires, there is used a press frame with coining performed for bonding wire-bonded portions of leads.

In a leadless package type semiconductor device, leads are short and may fall off after molding, so from the standpoint of strengthening the adhesion between the leads and molding resin, a notch is formed in part of the surface of each lead at a position with which the molding resin comes into contact, the notch being depressed in a direction intersecting the lead surface.

As to QPN, a description is found, for example, in Japanese patent laid-open No. 2005-276890. In this Japanese patent laid-open No. 2005-276890 is disclosed a technique such that a bonding wire-coupled portion of each lead in a leadless package type semiconductor device is depressed by etching or coining and a bonding wire loop height is made smaller than the amount of that depression, thereby preventing the bonding wire from being exposed from a lower surface of a sealing body.

In this Japanese patent laid-open No. 2005-276890, there also is disclosed a technique such that a depression is formed in a surface of each lead on the side opposite to a bonding wire-bonded surface of the lead to strengthen the adhesion between the lead and molding resin, thereby preventing the lead from falling off.

Moreover, in Japanese patent laid-open No. Hei 7 (1995)-245365, there is disclosed a technique related to a method of manufacturing a lead frame for a multi-pin package. According to this technique, the tips of inner leads are subjected to coining so that the respective coining areas are equal, thereby preventing dislocation of leads and shorting between adjacent leads. As a method for making the coining areas equal there is disclosed in this Japanese patent laid-open No. Hei 7 (1995)-245365, a technique such that a slant surface is formed, the slant surface having a lower side corresponding to the tip side of each inner lead.

In paragraph [0022] of this Japanese patent laid-open No. Hei 7 (1995)-245365, there is disclosed a problem that the tips of inner leads spring up as a result of coining.

### SUMMARY OF THE INVENTION

However, the present inventors have found out that the above leadless package type semiconductor device using the press frame involves the following problems. This point will be described below with reference to FIGS. 1 to 10.

FIG. 1 is a sectional view of a principal portion of a lead 50 before coining. In the lead 50, the left side in FIG. 1 indicates a front end portion toward a semiconductor chip. A V-shaped groove 51 extending in a direction intersecting an upper surface of the lead 50 is formed on the lead upper surface in the lead width direction.

FIGS. 2 to 4 are sectional views of the principal portion of the lead 50 being subjected to coining. First, as shown in FIG. 2, a coining punch 52 is disposed above the upper surface of the lead 50. A pressing surface of the coining punch 52 is nearly parallel to the upper surface of the lead 50. Subsequently, the coining punch 52 is brought down and is pressed against the front end portion of the lead 50 to depress the lead front end portion. Thereafter, as shown in FIG. 4, the coining punch 52 is raised and spaced away from the lead 50. At this time, the front end portion of the lead 50 springs up (deforms itself) with the groove 51 as a fulcrum, the groove 51 being formed on the upper surface of the lead 50.

FIG. 5 is a sectional view of a principal portion of a semiconductor device after molding. After the coining process for the lead 50, a silver (Ag) plating layer 53 is formed on the upper surface of the front end portion of the lead 50, then a bonding wire 54 is bonded to an upper surface of the silver plating layer 53, followed by molding. In the molding process, a sealing body 55 is formed using resin. At this time, as noted above, a gap is formed between a lower mold of a molding die and a lower surface of the lead 50 because the front end portion of the lead 50 is in a state in which it springs upward. Molding resin gets into the gap and a resin burr (resin flash) 55a is formed which covers a part of the lower surface of the lead 50. Consequently, there arises the problem that when plating the surface of the lead 50 subsequently, the resin flash 55a is an obstacle to forming a plating layer on the lower surface of the lead 50 and it becomes impossible to mount the semiconductor device onto a wiring substrate.

If the amount of depression of the lead 50 in the coining process is decreased, it becomes possible to suppress spring-up of the front end portion of the lead 50 and diminish or prevent defective mounting of the semiconductor device which is attributable to the aforesaid resin flash. In this case, however, there arise the following problem. This point will now be described with reference to FIGS. 6 and 7. FIG. 6 is a sectional view of principal portions of leads 50 in a conveyed or stored state of lead frames stackedly after coining. FIG. 7 is a sectional view of a principal portion of a lead 50 after wire bonding.

As noted above, if the amount of depression of the upper surface of the front end portion of the lead in the coining process is small, as shown in FIG. 6, there sometimes occurs a case where at the time of conveying or storing lead frames stackedly, the lower surface of the lead 50 in an upper lead frame comes into contact with the upper surface (the surface on which the plating layer 53 is formed) of the lead 50 in a lower lead frame. As a result, the plating layer 53 on the upper surface of the front end portion of the lower lead 50 is scratched frictionally. If wiring bonding is performed in this state, as shown in FIG. 7, the bonding wire 54 is bonded to the frictionally scratched plating layer 53 present on the upper surface of the front end portion of the lead 50, so that there occurs a bonding defect.

It is an object of the present invention to provide a technique capable of improving the semiconductor device manufacturing yield.

The above and other objects and novel features of the present invention will become apparent from the following description and the accompanying drawings.

The following is an outline of typical modes of the present invention as disclosed herein.

According to the present invention there is provided a semiconductor device comprising: a sealing body having a first main surface and a second main surface, the first and second main surfaces being positioned on mutually opposite sides in the thickness direction of the sealing body; a semiconductor chip sealed within the sealing body; a chip mounting portion sealed inside the sealing body and mounting the semiconductor chip thereover; a plurality of leads partially exposed from the first main surface of the sealing body; and a plurality of bonding wires for coupling the semiconductor chip electrically to the plural leads, wherein a notch is formed in a portion of each of the leads to which portion any of the bonding wires is not bonded and with which portion the sealing body comes into contact, wherein a coining work is performed for a portion to which an associated one of the bonding wires is bonded, of each of the leads, and wherein in the portion to which an associated one of the bonding wires is coupled, of each of the leads, the amount of depression at a position relatively close to the semiconductor chip is larger than that at a position relatively distant from the semiconductor chip.

The following is a brief description of an effect obtained by the typical mode of the present invention as disclosed herein.

Since in the portion of each of the leads to which portion an associated one of the bonding wires is bonded the amount of depression at a position relatively close to the semiconductor chip is larger than that at a position relatively distant from the semiconductor chip, it is possible to improve the semiconductor device manufacturing yield.

### BRIEF DESCRIPTION OF THE DRAWINGS

FIG. 1 is a sectional view of a principal portion of a lead before coining;

FIG. 2 is a sectional view of the principal portion of the lead being subjected to coining;

FIG. 3 is a sectional view of the principal portion of the lead during coining which follows FIG. 2;

FIG. 4 is a sectional view of the principal portion of the lead being subjected to coining which follows FIG. 3;

FIG. 5 is a sectional view of a principal portion of a semiconductor device after molding;

FIG. 6 is a sectional view of principal portions of leads in a stackedly conveyed or stored state of lead frames after coining;

FIG. 7 is a sectional view of a principal portion of a lead after wire bonding;

FIG. 8 is a manufacturing flow chart showing a semiconductor device manufacturing method according to an embodiment of the present invention;

FIG. 9 is a plan view of a unit area in a lead frame after a chip mounting process shown in FIG. 8;

FIG. 10 is an enlarged sectional view taken on line X1-X1 in FIG. 9;

FIG. 11 is an enlarged sectional view taken on line X2-X2 in FIG. 9;

FIG. 12 is an enlarged sectional view of a principal portion of a lead in a third main surface forming process for a lead frame;

FIG. 13 is an enlarged sectional view of the principal portion of the lead in the third main surface forming process for the lead frame which follows FIG. 12;

FIG. 14 is an enlarged sectional view of the principal portion of the lead in the third main surface forming process for the lead frame which follows FIG. 13;

FIG. 15 is an enlarged sectional view of principal portions of leads in a stackedly conveyed or stored state of two lead frames after coining;

FIG. 16 is a plan view of a unit area in a lead frame after a wire bonding process shown in FIG. 8;

FIG. 17 is an enlarged sectional view taken on line X1-X1 in FIG. 16;

FIG. 18 is an enlarged sectional view taken on line X2-X2 in FIG. 16;

FIG. 19 is a plan view of a unit area of a lead frame after a molding process shown in FIG. 8;

FIG. 20 is an enlarged sectional view taken on line X1-X1 in FIG. 19;

FIG. 21 is an enlarged sectional view of portion A in FIG. 20 taken on line X2-X2 in FIG. 19;

FIG. 22 is an entire plan view of a semiconductor device after a cutting process shown in FIG. 8;

FIG. 23 is a side view of the semiconductor device shown in FIG. 22;

FIG. 24 is an enlarged sectional view taken on line X3-X3 in FIG. 22; and

FIG. 25 is an enlarged sectional view taken on line X4-X4 in FIG. 22.

### DETAILED DESCRIPTION OF THE PREFERRED EMBODIMENT

Where required for convenience' sake, the following embodiment will be described in a divided manner into plural sections or embodiments, but unless otherwise mentioned, they are not unrelated to each other but are in a relation such that one is a modification or a detailed or supplementary explanation of part or the whole of the other. In the following embodiment, when reference is made to the number of elements (including the number, numerical value, quantity and range), no limitation is made to the number referred to, but numerals above and below the number referred to will do as well unless otherwise mentioned and except the case where it is basically evident that limitation is made to the number referred to. It goes without saying that in the following embodiment its constituent elements (including constituent steps) are not always essential unless otherwise mentioned and except the case where they are considered essential basically obviously. Likewise, it is to be understood that when reference is made to the shapes and a positional relation of constituent elements in the following embodiment, those substantially closely similar to or resembling such shapes, etc. are also included unless otherwise mentioned and except the case where a negative answer is evident basically. This is also true of the foregoing numerical value and range. Further, in all of the drawings for illustrating the following embodiment, portions having the same functions are identified by like reference numerals, and repeated explanations thereof will be omitted if possible.

An embodiment of the present invention will be described in detail hereinunder with reference to the accompanying drawings.

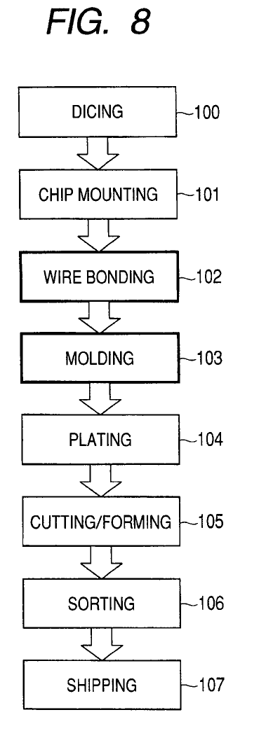

A semiconductor device manufacturing method embodying the present invention will be described below with reference to a manufacturing flow chart of FIG. 8 and FIGS. 9 to 25.

First, a semiconductor wafer having gone through a wafer process (pre-process) is subjected to dicing to divide the wafer into plural semiconductor chips (step 100 in FIG. 8). For example, the semiconductor wafer is a thin semiconductor sheet of a single crystal of silicon (Si) having a generally circular shape in plan. A desired integrated circuit is formed on a main surface of each semiconductor chip.

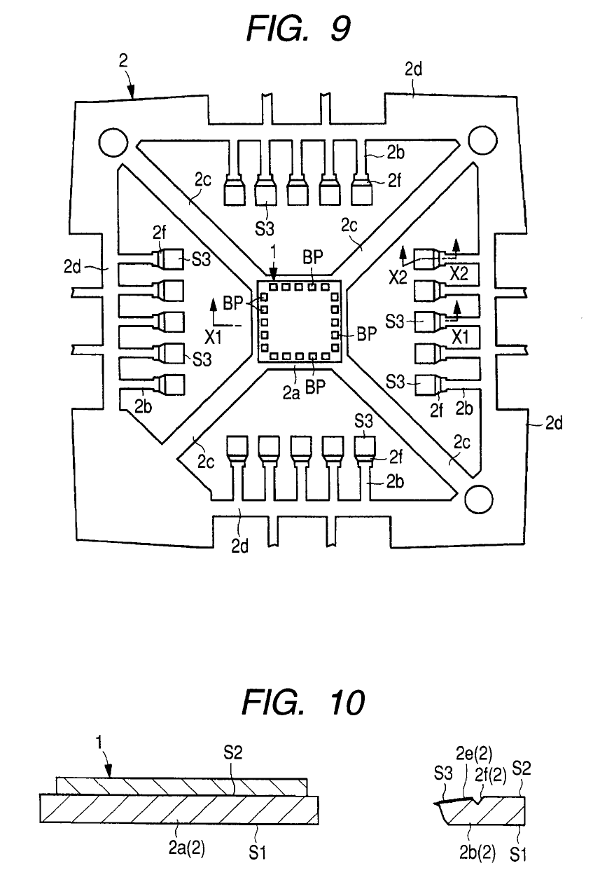

Then, as shown in FIGS. 9 and 10, the semiconductor chip 1 is placed on a die pad (a tab, a chip mounting portion) 2a of a lead frame 2 (step 101 in FIG. 8).

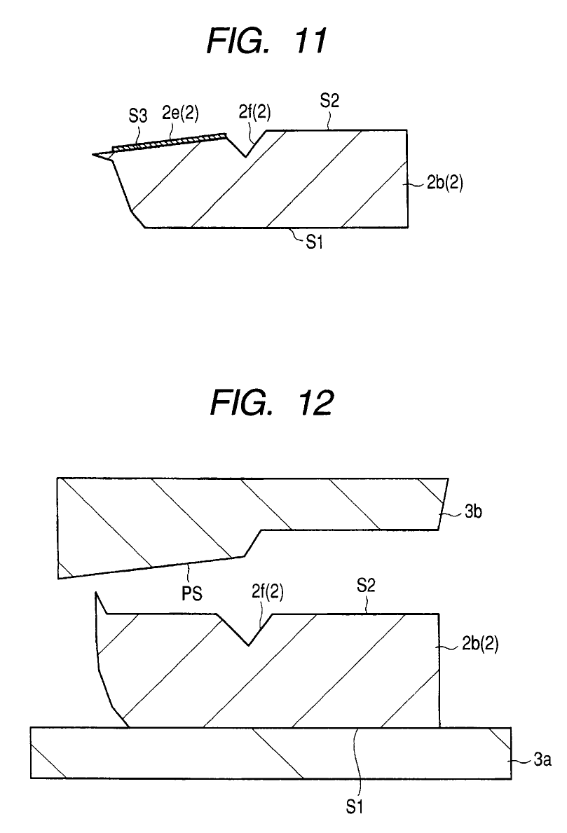

FIG. 9 is a plan view of a unit area in the lead frame 2 after the chip mounting process, FIG. 10 is an enlarged sectional view taken on line X1-X1 in FIG. 9, and FIG. 11 is an enlarged sectional view taken on line X2-X2 in FIG. 9.

The semiconductor chip 1 is, for example, a thin semiconductor sheet of a square shape in plan and is bonded and fixed to the die pad 2a in a state in which a main surface thereof faces up and a back surface thereof faces the die pad 2a. Plural bonding pads (hereinafter referred to simply as pads) BP are arranged side by side near and along the outer periphery of the chip main surface. The pads BP are electrically coupled to the integrated circuit on the main surface of the semiconductor chip 1.

The lead frame is a thin metallic sheet formed of, for example, copper (Cu) or 42 alloy. It has a first main surface S1 and a second main surface S2, the first and second main surfaces S1 and S2 being positioned on mutually opposite sides in the frame thickness direction.

Plural unit areas arranged in one row or in a matrix shape within the first and second main surfaces S1, S2 of the lead frame 2. In each such unit area of the lead frame 2 there are arranged the die pad 2a, plural leads 2b arranged to as to surround the outer periphery of the die pad 2a, suspending leads 2c extending outwards from four corners of the die pad 2a, and a frame portion 2d which supports the leads 2b and the suspending leads 2c.

Each of the leads 2b and each of the suspending leads 2c are coupled at respective one ends to the frame portion 2d integrally and are thereby supported by the lead frame 2.

At a front end portion of each lead 2b on the second main surface side and on the semiconductor chip 1 side there is formed a third main surface S3 which is inclined relative to the second main surface of the lead frame 2. A plating layer 2e of, for example, silver (Ag) is formed on the third main surface S3. A bonding wire to be described later is bonded to the portion of the lead where the plating layer 2e is formed.

In the second main surface S2 of each lead 2b and at a position retreated by an amount corresponding to the third main surface S3 from the front end of the lead 2b on the semiconductor chip 1 side, there is formed a notch 2f depressed in a direction intersecting the second main surface S2 and formed so as to cross the longitudinal direction of each lead 2b. The notch 2f is formed for improving the adhesion between molding resin and the lead 2b after a molding process to be described later and for suppressing or preventing fall-off of the lead 2b. Therefore, the notch 2f is formed in the portion covered with molding resin and to which the bonding wire to be described later is not bonded.

A method for forming the third main surface S3 of the lead 2b will be described below with reference to FIGS. 12 to 14, which are enlarged sectional views of a principal portion of the lead 2b during formation of the third main surface S3.

First, as shown in FIG. 12, the lead frame 2 after formation of the notches 2f is placed on a coining base 3a so that its first main surface S1 faces the coining base 3a and its second main surface S2 faces a coining punch 3b. A lead pressing surface PS of the coining punch 3b is inclined relative to the second main surface of each lead 2b. That is, the lead pressing surface PS of the coining punch 3b is inclined so as to become lower gradually toward the front end portion of each lead 2b.

Subsequently, as shown in FIG. 13, the lead pressing surface PS of the coining punch 3b is pressed against the second main surface S2 side of the lead front end portion to depress the lead front end portion. At this time, since the lead pressing surface PS of the coining punch 3b is formed obliquely, the amount of depression of the front end portion of the lead 2b at a position relatively close to the semiconductor chip 1 is larger than that at a position relatively distant from the semiconductor chip (oblique coining). Further, the coining is performed so that the amount of depression of the lead 2b becomes larger than the thickness of the plating layer 2e.

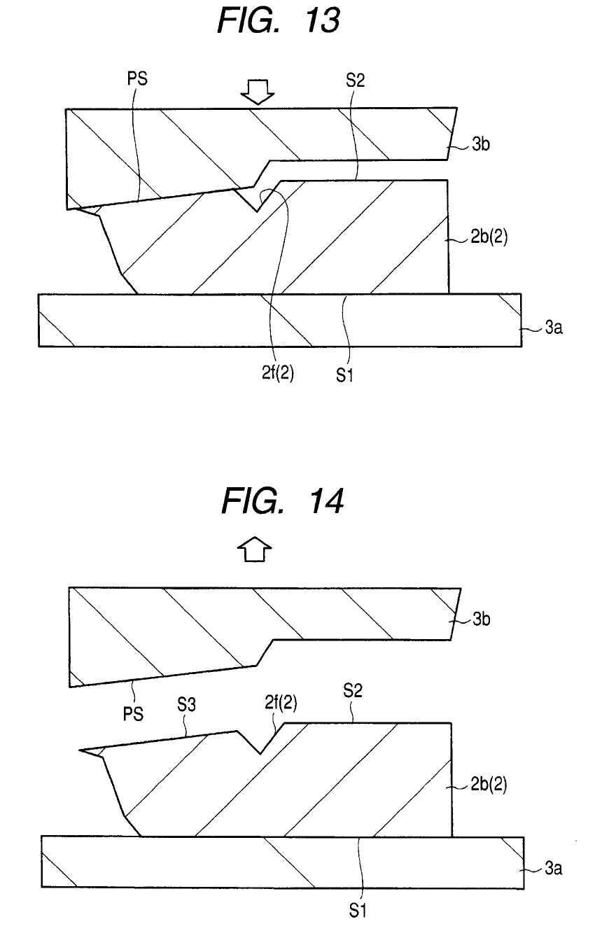

Thereafter, as shown in FIG. 14, the coining punch 3b is moved away from the lead 2b. In this way the third main surface S3 inclined relative to the first and second main surfaces S1, S2 of the lead 2b is formed at the front end portion on the semiconductor chip 1 side of the lead 2b and at the position against which the lead pressing surface PS of the coining punch 3b is pressed.

The third main surface S3 is formed from the notch 2f toward the front end on the semiconductor chip 1 side of the lead 2b. When seen in plan, the third main surface S3 is in a quadrangular shape which is wider than the other portion of the lead 2b. When seen in section, the third main surface S3 is formed so that its height (distance from the first main surface S1 of the lead 2b) becomes gradually lower (shorter) from the notch 2f toward the front end of the lead 2b. The depressive size of the third main surface S3 is set at a size such that when lead frames 2 are stacked in the thickness direction, the first main surface S1 of the upper lead 2b does not overlap the plating layer 2e on the third main surface S3 of the lower lead 2b. The third main surface S3 is inclined also relative to a mounting surface of the semiconductor device.

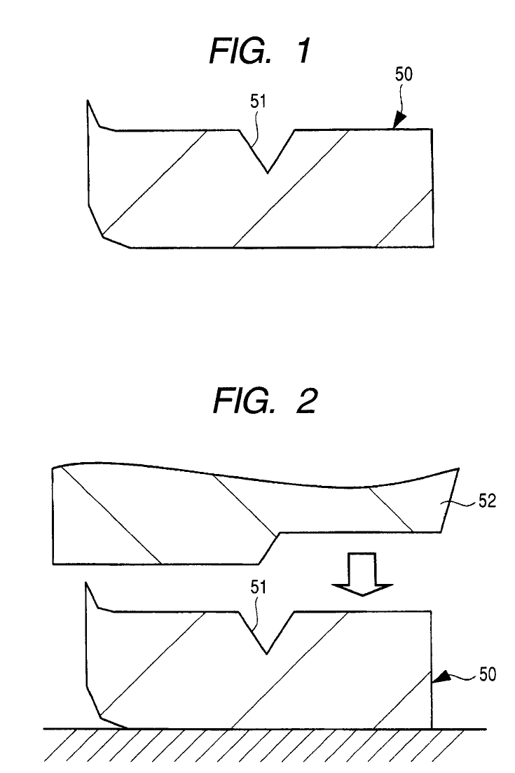

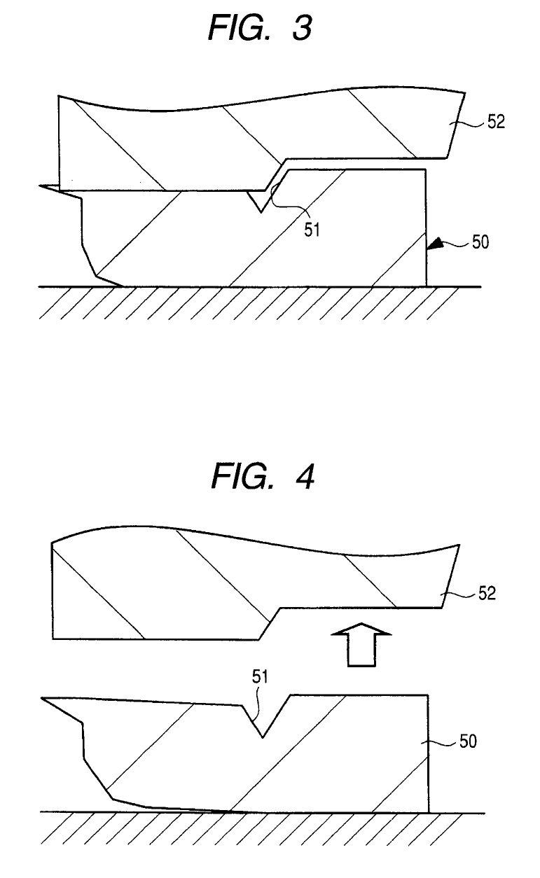

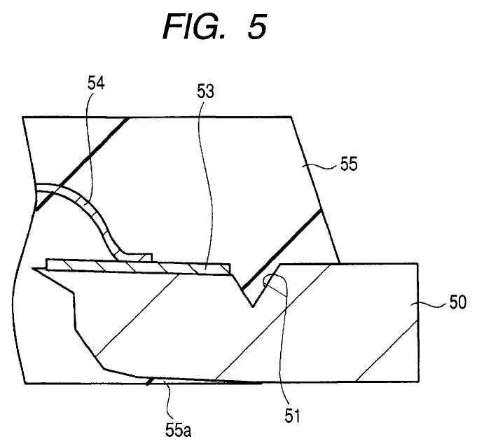

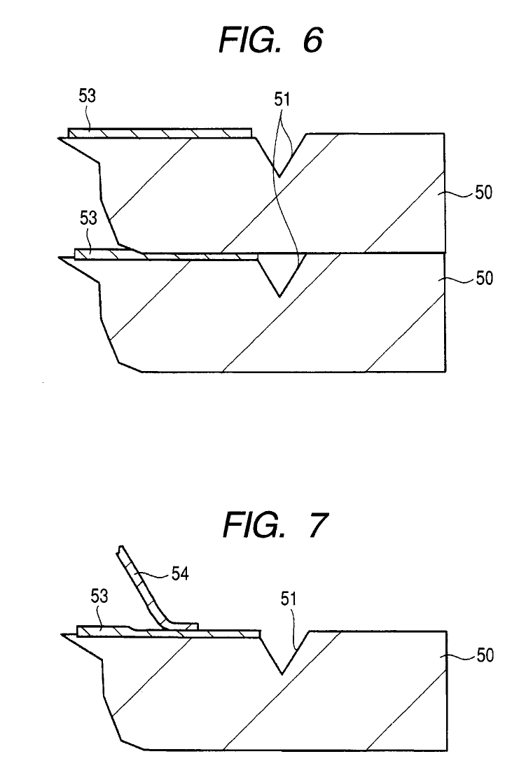

By adopting such an oblique coining process in this embodiment it is possible to effect coining shallower than in the case described previously in connection with FIGS. 1 to 4. Therefore, even if the notch 2f is formed in the front end portion of each lead 2b, it is possible to suppress or prevent spring-up of the lead front end portion.

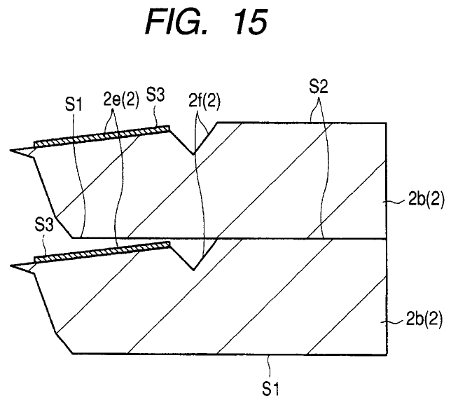

FIG. 15 is an enlarged sectional view of principal portions of leads 2b in a stackedly conveyed or stored state of two lead frames 2 after the above coining process. In this embodiment, not only the third main surface 3S of the front end portion of each lead 2b is inclined, but also the amount of depression of the lead 2b is set larger than the thickness of the plating layer 2e. Consequently, when plural leads 2 are stacked, it is possible to decrease or prevent contact of the first main surface (lower surface) S1 of the upper lead 2b with the plating layer 2e on the third main surface S3 of the lower lead 2b. Accordingly, it is possible to decrease or prevent the formation of a frictional scratch on the plating layer 2e of the third main surface S3 at the front end portion of the lower lead 2b.

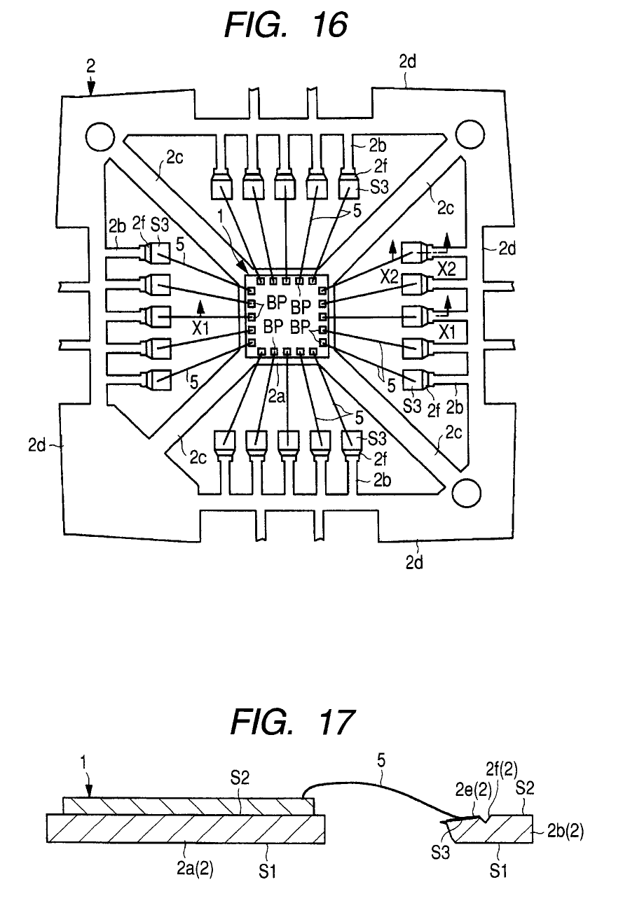

Subsequently, as shown in FIGS. 16, 17 and 18, pads BP on the semiconductor chip 1 and the leads 2b of the lead frame 2 are coupled together electrically through bonding wires (simply “wires” hereinafter) (step 102 in FIG. 8).

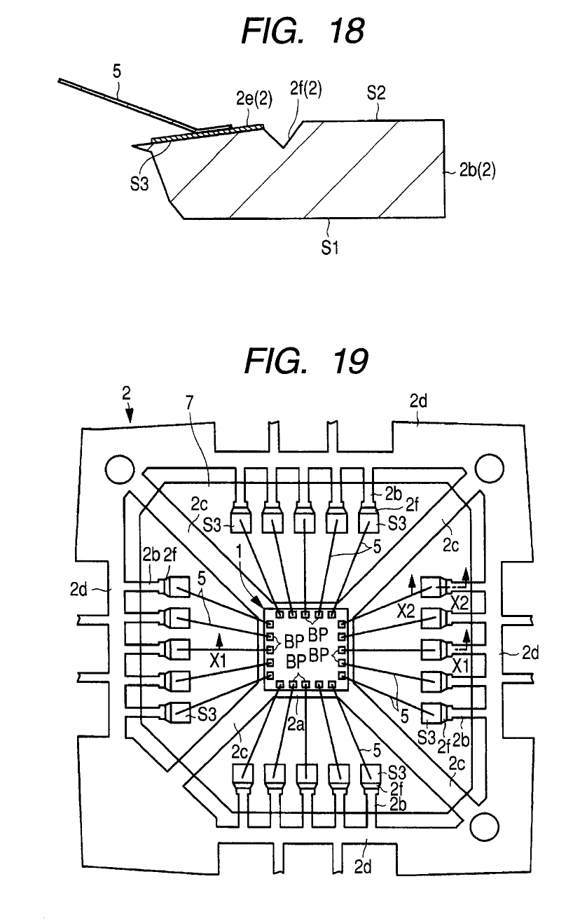

FIG. 16 is a plan view of a unit area in the lead frame 2 after the wire bonding process, FIG. 17 is an enlarged sectional view taken on line X1-X1 in FIG. 16, and FIG. 18 is an enlarged sectional view taken on line X2-X2 in FIG. 16.

The wires 5 are formed of gold (Au) for example. The wires 5 are bonded for example by a normal bonding method. That is, one end (first bonding point) of each wire 5 is bonded to an associated pad BP on the semiconductor chip 1, while the other end (second bonding point) thereof is bonded to the plating layer 2e on the third main surface S3 of the associated lead 2b. The second bonding point of each wire 5 is positioned about 0.15 mm away from the front end of the lead 2b.

In this embodiment, since it is possible to diminish or prevent a rubbing defect of the plating layers 2e of the leads 2b, one ends (second bonding points) of the wires 5 can be bonded in a satisfactory manner to the third main surfaces S3 (plating layers 2e) of the front end portions of the leads 2b. That is, it is possible to improve the bondability between the wires 5 and the leads 2b and hence possible to improve the yield and reliability of the semiconductor device.

Thereafter, a transfer molding process is performed to form a sealing body 7 in each unit area, as shown in FIGS. 19, 20 and 21.

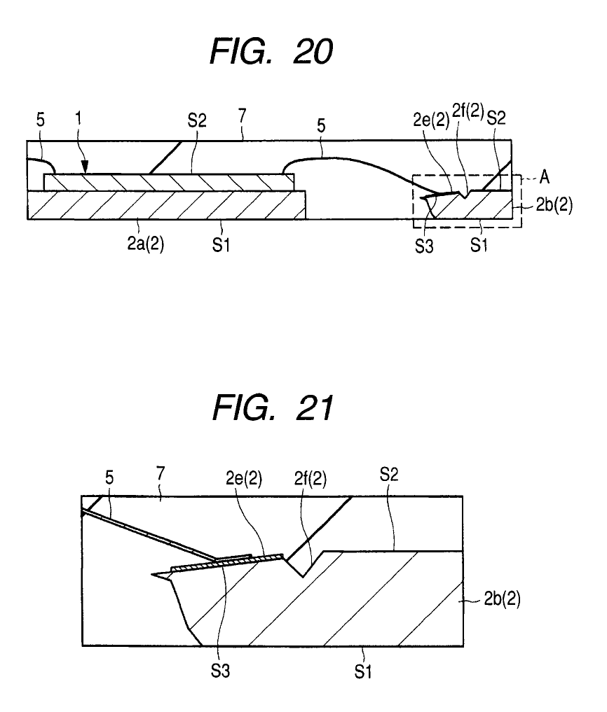

FIG. 19 is a plan view of a unit area in the lead frame 2, FIG. 20 is an enlarged sectional view taken on line X1-X1 in FIG. 19, and FIG. 21 is an enlarged sectional view of portion A in FIG. 20, taken on line X2-X2 in FIG. 19. In FIG. 19, the interior of the sealing body 7 is seen through in order to make the drawing easier to see.

The sealing body 7 is formed of an epoxy resin for example. The semiconductor chip 1, wires 5, part of the die pad 2a, part of the leads 2b and part of the suspending leads 2c are sealed with the sealing body 7.

In this embodiment, as noted above, since it is possible to suppress or prevent spring-up of the front end portions of the leads 2b, it is possible to make small or eliminate the gap between the first main surface S1 of each lead 2b and the lead frame mounting surface of the lower mold of the molding die. Consequently, it is possible to diminish or prevent the adhesion of the foregoing resin burr (resin flash) to the first main surface S1 of each lead 2b.

Next, a plating layer of silver for example is formed on the surface of the lead frame 2 (leads 2b) which surface is exposed from the sealing body 7 (step 104 in FIG. 8). At this time, as noted above, since in this embodiment it is possible to diminish or prevent the adhesion of the foregoing resin burr (resin flash) to the first main surface S1 of each lead 2b, it is possible to diminish or prevent insufficient wetting of plating.

Subsequently, part of the lead frame 2 is cut to form the lead frame into the shape of leads 2b (step 105 in FIG. 8), whereby individual semiconductor devices are separated from the lead frame 2.

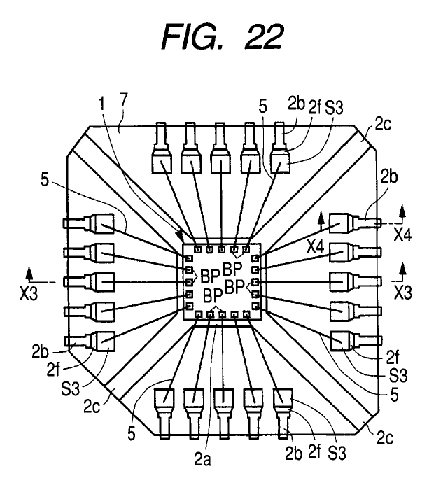

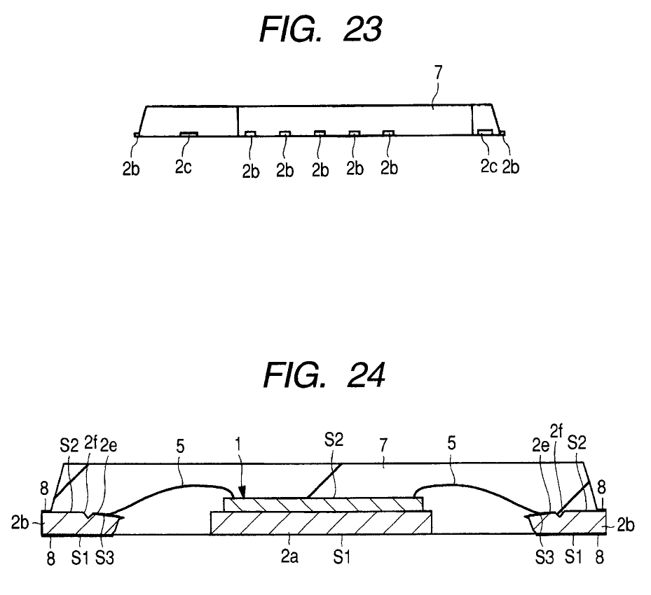

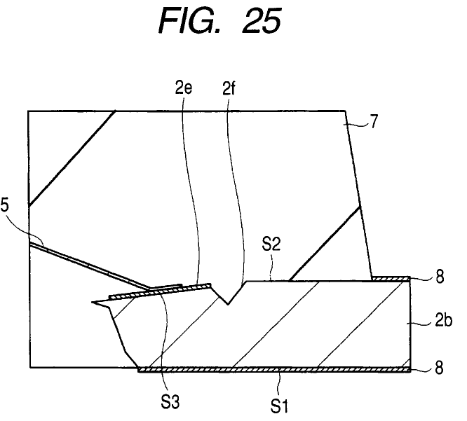

FIG. 22 is an entire plan view of the semiconductor device after the cutting process, FIG. 23 is a side view thereof, FIG. 24 is an enlarged sectional view taken on line X3-X3 in FIG. 22, and FIG. 25 is an enlarged sectional view taken on line X4-X4 in FIG. 22. In FIG. 22, the interior of the sealing body 7 is seen through in order to make the drawing easier to see.

The semiconductor device of this embodiment is of a QFN (Quad Flat Non leaded package) configuration for example. According to this configuration, the leads 2b are partially exposed from side faces and back surface of the sealing body 7, but the length of each lead 2b projecting from a side face of the sealing body 7 is short.

On the exposed surface of each lead 2b (exclusive of the cut faces of the lead frame 2) there is formed a plating layer 8 by the plating process (104) in FIG. 8. According to this embodiment, as noted above, it is possible to diminish or prevent the adhesion of the foregoing resin burr (resin flash) to the first main surface S1 of each lead 2b and hence possible to form the plating layer 8 in a satisfactory manner on the first main surface S1 of each lead 2b. Therefore, it is possible to diminish or prevent the occurrence of a packaging defect of the semiconductor device.

According to the QFN configuration the leads 2b are short and may fall off from the sealing body 7. In this embodiment, however, since the notch 2f is formed in the second main surface S2 of each lead 2b, it is possible to improve the adhesion between the lead 2b and the sealing body (molding resin) and hence possible to suppress or prevent falling-off of the short lead 2b.

Thereafter, good products are sorted out from among plural semiconductor devices thus obtained and are shipped (steps 106 and 107 in FIG. 8).

Although an embodiment of the present invention has been described above concretely, it goes without saying that the present invention is not limited to the above embodiment, but that various changes may be made within the scope not departing from the gist of the invention.

What is claimed is:

1. A method of manufacturing a semiconductor device, comprising the steps of:
(a) providing a lead frame having a first main surface and a second main surface, the first and second main surfaces being positioned on mutually opposite sides in the thickness direction of the lead frame, the lead frame further having, in each unit area, a chip mounting portion and a plurality of leads;
(b) mounting a semiconductor chip onto the second main surface of the chip mounting portion of the lead frame;
(c) coupling the semiconductor chip and the leads of the lead frame electrically with each other through bonding wires;
(d) forming a sealing body so as to cover a part of each of the leads, the whole of the semiconductor chip and further cover the whole of the bonding wires;
(e) plating exposed portions of the leads exposed from the sealing body; and
(f) cutting a part of the lead frame and separating the sealing body from the lead frame,
wherein in the lead frame provided in the step (a):
(a1) a notch is formed in a portion of the second main surface of each of the leads of the lead frame, the portion being a portion to which any of the bonding wires is not bonded and which is covered with the sealing body, the notch being depressed in a direction intersecting the second main surface of each of the leads and formed so as to cross the longitudinal direction of each of the leads;
(a2) coining is performed for a portion to which an associated one of the bonding wires is bonded, of the second main surface of each of the leads of the lead frame, in such a manner that the amount of depression at a position relatively close to the semiconductor chip is larger than that at a position relatively distant from the semiconductor chip; and
(a3) plating is performed for the portion to which an associated one of the bonding wires is bonded, of each of the leads of the lead frame.

2. A method according to claim 1, wherein in the step (a) a third main surface inclined relative to the second main surface of each of the leads of the lead frame is formed at the portion to which an associated one of the bonding wires is bonded, on the second main surface side of each of the leads.

3. A method according to claim 1, wherein the amount of depression of each of the leads of the lead frame in the step (a2) is larger than the thickness of the plating in the step (a3).

4. A method of manufacturing a semiconductor device, comprising the steps of:
(a) providing a lead frame having a first main surface and a second main surface, the first and second main surfaces being positioned on mutually opposite sides in the thickness direction of the lead frame, the lead frame further having in each unit area a chip mounting portion and a plurality of leads;
(b) mounting a semiconductor chip onto the second main surface of the chip mounting portion of the lead frame;
(c) coupling the semiconductor chip and the leads of the lead frame electrically with each other through bonding wires;
(d) forming a sealing body so as to cover a part of each of the leads, the whole of the semiconductor chip and further cover the whole of the bonding wires;
(e) plating exposed portions of the leads exposed from the sealing body; and
(f) cutting a part of the lead frame and separating the sealing body from the lead frame,
the step (a) comprising the steps of:
(a1) forming a notch in a portion of the second main surface of each of the leads of the lead frame, the portion being a portion to which any of the bonding wires is not bonded and which is covered with the sealing body, the notch being depressed in a direction intersecting the second main surface of each of the leads and formed so as to cross the longitudinal direction of each of the leads;
(a2) performing a coining work for a portion to which an associated one of the bonding wires is bonded, of the second main surface of each of the leads of the lead frame;
(a3) performing a plating work for the portion to which an associated one of the bonding wires is bonded, of each of the leads of the lead frame; and
(a4) stacking said lead frames in the thickness direction of the lead frames after the steps (a1) to (a3) in such a manner that the first and second main surfaces of an overlying one of the lead frames and those of an underlying one of the lead frames confront each other,
the coining work in the step (a2) being performed in such a manner that the amount of depression at a position relatively close to the semiconductor chip is larger than that at a position relatively distant from the semiconductor chip.

5. A method according to claim 4, wherein in the step (a2) a third main surface inclined relative to the second main surface of each of the leads is formed at the portion to which an associated one of the bonding wires is bonded, on the second main surface side of each of the leads.

6. A method according to claim, 4, wherein the amount of depression in the step (a2) is larger than the thickness of the plating performed in the step (a3).

7. A semiconductor device comprising:
a sealing body having a first main surface and a second main surface that are positioned on mutually opposite sides in the thickness direction of the sealing body;
a semiconductor chip sealed within the sealing body;
a chip mounting portion sealed in the sealing body and mounting the semiconductor chip thereover;
a plurality of leads partially exposed from the first main surface of the sealing body; and
a plurality of bonding wires for coupling the semiconductor chip and the leads electrically with each other,
wherein a coining work is performed for a portion to which an associated one of the bonding wires is bonded, of the second main surface of each of the leads,
wherein a plating work is performed for the portion to which an associated one of the bonding wires is bonded and which is subjected to the coining work, of the second main surface of each of the leads, and
wherein, in the portion to which an associated one of the bonding wires is bonded, of the second main surface of each of the leads, the amount of depression at a position relatively close to the semiconductor chip is larger than that at a position relatively distant from the semiconductor chip.

8. A semiconductor device according to claim 7, wherein a third main surface inclined relative to the second main surface of each of the leads is formed at the portion to which an associated one of the bonding wires is bonded, on the second main surface side of each of the leads.

9. A semiconductor device according to claim 7, wherein the amount of depression of the portion of the second main surface of each of the leads to which portion an associated one of the bonding wires is bonded is larger than the thickness of the plating applied to the portion to which an associated one of the bonding wires is bonded.
